(19) United States
(12) Patent Application Publication
(10) Pub. No.: US 2025/0185399 A1
(43) Pub. Date: Jun. 5, 2025

(54) SOLID-STATE IMAGING DEVICE

(71) Applicant: SONY SEMICONDUCTOR SOLUTIONS CORPORATION, KANAGAWA (JP)

(72) Inventor: MASASHIGE MORITOKI, KUMAMOTO (JP)

(21) Appl. No.: 18/844,268

(22) PCT Filed: Jan. 23, 2023
(86) PCT No.: PCT/JP2023/001957

§ 371 Date: Sep. 5, 2024

(30) Foreign Application Priority Data
Mar. 18, 2022 (JP) 2022-043972

(51) Int. Cl. H10F 39/00

(52) U.S. Cl. CPC H10F 39/807; H10F 39/802; H10F 39/80377; H10F 39/811

(57) ABSTRACT

A pixel transistor is disposed in a trench that isolates a pixel of a solid-state imaging device. The solid-state imaging device includes the trench and the pixel transistor. The trench isolates the pixel. The pixel transistor forms a channel region in a direction intersecting the depth direction of the trench along the side surface of the trench. At least a part of a gate electrode of the pixel transistor may be located in the trench. At least one of a source, a drain, or a floating diffusion of the pixel transistor may be located on the side surface of the trench. The pixel transistor may include at least one of a drive transistor, a selection transistor, a reset transistor, or a transfer transistor.

### TECHNICAL FIELD

The present technology relates to a solid-state imaging device. Specifically, the present technology relates to a pixel transistor of a solid-state imaging device.

### BACKGROUND ART

In a solid-state imaging device, an element isolation structure is provided to isolate each pixel. For example, a structure in which a front deep trench isolation (FDTI) and a rear deep trench isolation (RDTI) are employed as an element isolation structure has been disclosed (see, for example, Patent Document 1).

### CITATION LIST

### Patent Document

Patent Document 1: WO 2017/187957 A

### SUMMARY OF THE INVENTION

### Problems to be Solved by the Invention

In the above-described conventional technique, pixel transistors are disposed at positions separated from photodiodes by the FDTI. For this reason, it is necessary to secure another region for disposing the pixel transistors than the region for disposing the FDTI, and there is a possibility that the area of the photosensitive surface is reduced accordingly.

The present technology has been made in view of such a situation, and an object thereof is to dispose a pixel transistor in a trench for isolating pixels of a solid-state imaging device.

### Solutions to Problems

The present technology has been made to solve the above-described problems, and a first aspect thereof includes: a trench for isolating a pixel; and a pixel transistor that forms a channel region along a side surface of the trench in a direction intersecting a depth direction of the trench. This brings about an effect that the pixel transistor is disposed along the trench while a gate electrode of the pixel transistor is disposed in the trench.

Furthermore, in the first aspect, at least a part of a gate electrode of the pixel transistor is located in the trench. This brings about an effect that the gate width is enlarged in the depth direction of the trench while the pixel transistor is disposed along the trench.

Furthermore, in the first aspect, the direction intersecting the depth direction of the trench includes at least one of a column direction or a row direction. This brings about an effect that the pixel transistors are disposed on the side surfaces of the trench while isolating each of the pixels in the column direction and the row direction.

Furthermore, in the first aspect, the pixel transistor includes at least one of a drive transistor, a selection transistor, a reset transistor, or a transfer transistor. This brings about an effect of increasing the gate width while suppressing an increase in the area occupied by the drive transistor, the selection transistor, the reset transistor, and the transfer transistor on the pixels.

Furthermore, in the first aspect, at least one of a source, a drain, or a floating diffusion of the pixel transistor is located on the side surface of the trench. This brings about an effect that the operation of the pixel transistor is performed on the side surface side of the trench.

Furthermore, the first aspect further includes an insulating layer embedded in a part of the trench in the depth direction, in which a part of a gate electrode of the pixel transistor is located on the side surface of the trench on the insulating layer with a gate insulating film interposed between the part of the gate electrode and the side surface. This brings about an effect that the channel region of the pixel transistor is formed on the side surface of the trench while stability of pixel isolation is improved.

Furthermore, in the first aspect, a part of a gate electrode of the pixel transistor is located on the pixel. This brings about an effect that a contact area of the gate electrode is secured.

In addition, the first aspect further includes a spacer insulating layer located below the gate electrode on the pixel. This brings about an effect that the corner portion of the gate electrode located on the pixel is kept away from the pixel.

Furthermore, in the first aspect, at least one of sources, drains, or floating diffusions of adjacent pixels are isolated from each other by the trench. This brings about an effect that it is not necessary to connect the sources, the drains, and the floating diffusions of the adjacent pixels each other in the trench.

In addition, the first aspect further includes: a contact plug connected to each of sources, drains, and floating diffusions of adjacent pixels isolated from each other by the trench; and a wiring line that connects the sources, the drains, and the floating diffusions each other which are isolated by the trench, via the contact plug connected to each of the sources, the drains, and the floating diffusions isolated by the trench. This brings about an effect that the sources, the drains, and the floating diffusions isolated from each other by the trench are connected to each other.

Furthermore, the first aspect further includes a contact plug connected across the trench to each of sources, drains, and floating diffusions isolated from each other by the trench between adjacent pixels. This brings about an effect that the sources, the drains, and the floating diffusions isolated from each other by the trench are connected to each other.

In addition, the first aspect further includes a base layer that is connected across the trench to each of sources, drains, and floating diffusions isolated from each other by the trench between adjacent pixels, the base layer including the same material as a material of a gate electrode of the pixel transistor. This brings about an effect that the tip of the contact plug is prevented from entering the trench at the time of forming the contact plug.

Furthermore, in the first aspect, a part of the base layer connected to each of the sources and the drains is located in the trench. This brings about an effect that the widths in the depth direction of the source and the drain in the trench are enlarged according to the gate width in the depth direction of the gate electrode embedded in the trench.

Furthermore, in the first aspect, the materials of the gate electrode and the base layer include polycrystalline silicon into which impurities are introduced. This brings about an effect that the gate electrode and the base layer are collectively formed on the basis of the photolithography technique and the dry etching technique.

Furthermore, in the first aspect, a transfer transistor used as the pixel transistor has a planar structure, and an end in a width direction of a gate electrode of the transfer transistor is located on an insulating layer embedded in the trench. This brings about an effect that the uniformity in the gate width of the transfer transistor among pixels is improved.

Furthermore, in the first aspect, an end in a width direction of a gate electrode of a transfer transistor used as the pixel transistor is located on the side surface of the trench on the insulating layer with a gate insulating film interposed between the end and the side surface. This brings about an effect that the channel region of the transfer transistor is enlarged to the side surface side of the trench.

### BRIEF DESCRIPTION OF DRAWINGS

FIG. 1 is a block diagram illustrating a configuration example of an imaging device according to a first embodiment.

FIG. 2 is a block diagram illustrating a configuration example of a solid-state imaging device according to the first embodiment.

FIG. 3 is a diagram illustrating a circuit configuration example of a pixel according to the first embodiment.

FIG. 4 is a cross-sectional view illustrating a configuration example of pixels according to the first embodiment.

FIG. 5 is a cross-sectional view illustrating the configuration example of pixels according to the first embodiment in an enlarged manner.

FIG. 6 is a cross-sectional view illustrating the configuration example of pixels according to the first embodiment in a further enlarged manner.

FIG. 7 is a cross-sectional view illustrating a configuration example of pixels according to a second embodiment.

FIG. 8 is a cross-sectional view illustrating a configuration example of pixels according to a third embodiment.

FIG. 9 is a cross-sectional view illustrating the configuration example of pixels according to the third embodiment in an enlarged manner.

FIG. 10 is a cross-sectional view illustrating a configuration example of pixels according to a fourth embodiment.

FIG. 11 is a diagram illustrating a circuit configuration example of pixels according to a fifth embodiment.

FIG. 12 is a plan view illustrating a configuration example of a cell according to the fifth embodiment.

FIG. 13 is a cross-sectional view taken along line A1-B1 of the configuration example of the cell according to the fifth embodiment.

FIG. 14 is a cross-sectional view taken along line A2-B2 of the configuration example of the cell according to the fifth embodiment.

FIG. 15 is a cross-sectional view taken along line A3-B3 of the configuration example of the cell according to the fifth embodiment.

FIG. 16 is a cross-sectional view taken along line A4-B4 of the configuration example of the cell according to the fifth embodiment.

FIG. 17 is a plan view illustrating a configuration example of a cell according to a sixth embodiment.

FIG. 18 is a cross-sectional view taken along line A1-B1 of the configuration example of the cell according to the sixth embodiment.

FIG. 19 is a cross-sectional view taken along line A2-B2 of the configuration example of the cell according to the sixth embodiment.

FIG. 20 is a cross-sectional view taken along line A3-B3 of the configuration example of the cell according to the sixth embodiment.

FIG. 21 is a plan view illustrating a configuration example of a cell according to a seventh embodiment.

FIG. 22 is a cross-sectional view taken along line A1-B1 of the configuration example of the cell according to the seventh embodiment.

FIG. 23 is a cross-sectional view taken along line A2-B2 of the configuration example of the cell according to the seventh embodiment.

FIG. 24 is a cross-sectional view taken along line A3-B3 of the configuration example of the cell according to the seventh embodiment.

FIG. 25 is a plan view illustrating a configuration example of a cell according to an eighth embodiment.

FIG. 26 is a plan view illustrating a configuration example of a cell according to a ninth embodiment.

FIG. 27 is a cross-sectional view taken along line A5-B5 of the configuration example of the cell according to the ninth embodiment.

FIG. 28 is a cross-sectional view taken along line A6-B6 of the configuration example of the cell according to the ninth embodiment.

FIG. 29 is a plan view illustrating a configuration example of a cell according to a tenth embodiment.

FIG. 30 is a cross-sectional view taken along line A7-B7 of the configuration example of the cell according to the tenth embodiment.

FIG. 31 is a plan view illustrating a configuration example of a cell according to an eleventh embodiment.

FIG. 32 is a cross-sectional view taken along line A8-B8 of the configuration example of the cell according to the eleventh embodiment.

FIG. 33 is a diagram illustrating a circuit configuration example of pixels according to a twelfth embodiment.

FIG. 34 is a diagram illustrating a circuit configuration example of pixels according to a thirteenth embodiment.

### MODE FOR CARRYING OUT THE INVENTION

Modes for carrying out the present technology (hereinafter, referred to as embodiments) will be described below. The description will be given in the following order.
1. First Embodiment (example in which pixel transistor is provided in trench in 1-pixel-1-cell structure)
2. Second Embodiment (example in which spacer insulating layer is provided under gate electrode)
3. Third Embodiment (example in which pixel isolation region where pixel transistor is provided is configured by FDTI and RDTI)
4. Fourth Embodiment (example in which pixel isolation region where pixel transistor is provided is configured by FDTI and RDTI, and spacer insulating layer is provided under gate electrode)
5. Fifth Embodiment (example in which pixel transistor is provided in trench in 4-pixel-1-cell structure)
6. Sixth Embodiment (example in which contact plug connected in common with impurity diffusion layers of pixel transistors isolated by pixel isolation region is provided)
7. Seventh Embodiment (example in which base layer including the same material as that of gate electrode of pixel transistor is provided on impurity diffusion layers of pixel transistors)
8. Eighth Embodiment (example in which pixel transistor has double amplifier configuration)
9. Ninth Embodiment (example in which ends in width direction of gate electrode of transfer transistor are disposed on pixel isolation region)
10. Tenth Embodiment (example in which channel region of transfer transistor is enlarged to side surface side of trench)
11. Eleventh Embodiment (example in which base layer is provided on floating diffusions)
12. Twelfth Embodiment (example in which configuration in which pixel transistor is provided in trench is applied to 8-pixel-1-cell structure of two rows and four columns)
13. Thirteenth Embodiment (example in which configuration in which pixel transistor is provided in trench is applied to 8-pixel-1-cell structure of one row and eight columns)

### 1. First Embodiment

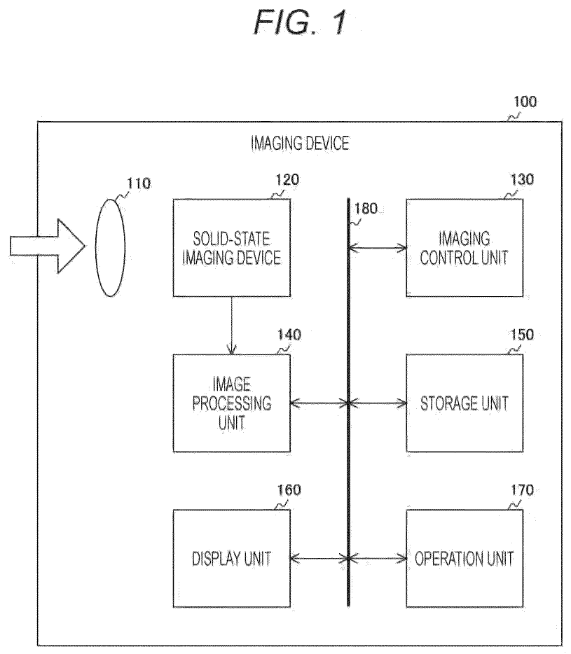

FIG. 1 is a block diagram illustrating a configuration example of an imaging device according to a first embodiment.

In FIG. 1, an imaging device 100 includes an optical system 110, a solid-state imaging device 120, an imaging control unit 130, an image processing unit 140, a storage unit 150, a display unit 160, and an operation unit 170. The imaging control unit 130, the image processing unit 140, the storage unit 150, the display unit 160, and the operation unit 170 are connected to each other via a bus 180.

The optical system 110 causes light from a subject to enter the solid-state imaging device 120, and forms an image of the subject on a light-receiving surface of the solid-state imaging device 120. The optical system 110 can include, for example, a focus lens, a zoom lens, a diaphragm, and the like.

The solid-state imaging device 120 converts light from the subject into an electric signal for each pixel, and digitizes and outputs the electric signal. The solid-state imaging device 120 is, for example, a complementary metal oxide semiconductor (CMOS) image sensor.

The imaging control unit 130 controls the imaging by the solid-state imaging device 120 on the basis of a command from the operation unit 170. At this time, the imaging control unit 130 can control exposure conditions, imaging timing, and the like of the solid-state imaging device 120.

The image processing unit 140 performs image processing on the basis of the output from the solid-state imaging device 120. The image processing is, for example, gamma correction, white balance processing, sharpness processing, or gradation conversion processing. The image processing unit 140 may include a processor that executes processing on the basis of software.

The storage unit 150 stores a captured image captured by the solid-state imaging device 120, and stores imaging parameters and the like of the solid-state imaging device 120. Furthermore, the storage unit 150 can store a program for operating the imaging device 120 on the basis of software. The storage unit 150 may include a read only memory (ROM), a random access memory (RAM), and a memory card.

The display unit 160 displays a captured image and displays various types of information supporting imaging operation. The display unit 160 may be a liquid crystal display or an organic electro luminescence (EL) display.

The operation unit 170 provides a user interface for operating the imaging device 100. The operation unit 170 may include, for example, a button, a dial, and a switch provided in the imaging device 100. The operation unit 170 may include a touch panel configured together with the display unit 160.

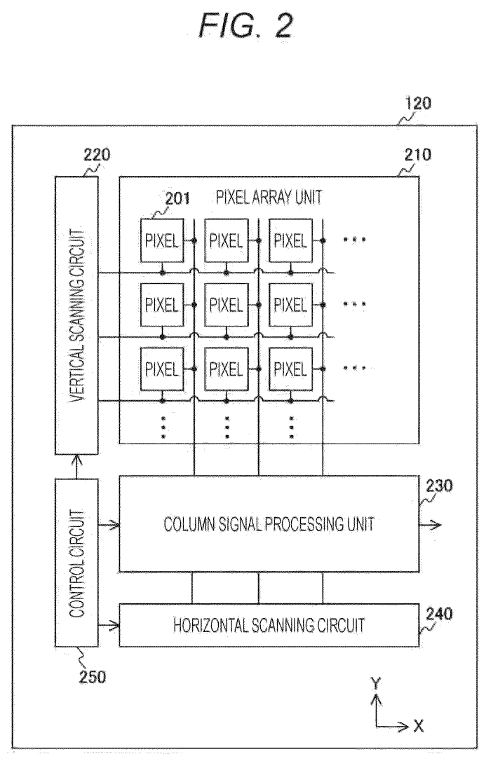

FIG. 2 is a block diagram illustrating a configuration example of the solid-state imaging device according to the first embodiment.

In FIG. 2, the solid-state imaging device 120 includes a pixel array unit 210, a vertical scanning circuit 220, a column signal processing unit 230, a horizontal scanning circuit 240, and a control circuit 250.

The pixel array unit 210 includes a plurality of pixels 201. The pixels 201 are arranged in a matrix along a row direction (also referred to as a horizontal direction) X and a column direction (also referred to as a vertical direction) Y.

The vertical scanning circuit 220 scans the pixels 201 to be read in the column direction Y. The vertical scanning circuit 220 may be configured using a vertical register.

The column signal processing unit 230 processes a signal transmitted from each pixel 201 in the column direction Y. For example, the column signal processing unit 230 can perform correlated double sampling (CDS) processing on the basis of the signal transmitted in the column direction Y from each pixel 201. Furthermore, the column signal processing unit 230 can perform analog to digital (AD) conversion processing on the basis of the signal transmitted from each pixel 201 in the column direction Y.

The horizontal scanning circuit 240 scans the pixels 201 to be read in the row direction X. The horizontal scanning circuit 240 may be configured using a horizontal register.

The control circuit 250 controls the vertical scanning circuit 220, the column signal processing unit 230, and the horizontal scanning circuit 240. For example, the control circuit 250 can control the scanning timing in the column direction Y, the scanning timing in the row direction X, and the processing timing of the column signal processing unit 230.

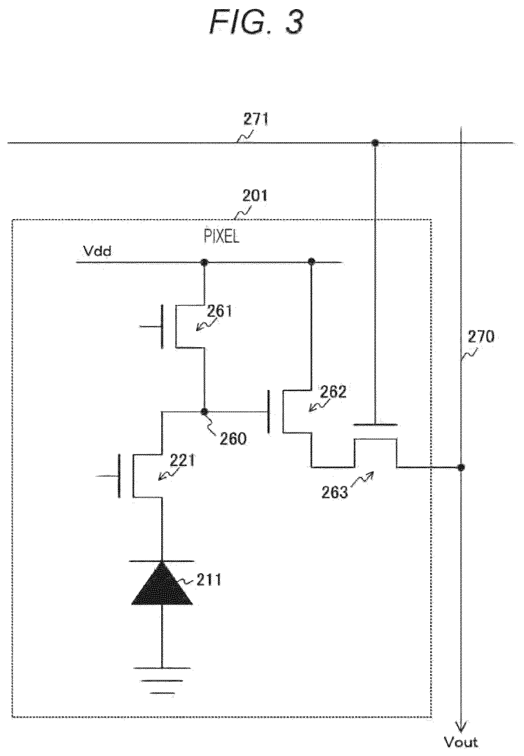

FIG. 3 is a diagram illustrating a circuit configuration example of a pixel according to the first embodiment.

In FIG. 3, the pixel 201 includes a photodiode 211, a transfer transistor 221, a reset transistor 261, a drive transistor 262, a selection transistor 263, and a floating diffusion 260.

The drive transistor 262 and the selection transistor 263 are connected in series. A cathode of the photodiode 211 is connected to the floating diffusion 260 via the transfer transistor 221. In addition, the floating diffusion 260 is connected to a power supply Vdd via the reset transistor 261. Furthermore, the power supply Vdd is connected to a vertical signal line 270 via a series circuit of the drive transistor 262 and the selection transistor 263. A gate electrode of the drive transistor 262 is connected to the floating diffusion 260, and a gate electrode of the selection transistor 263 is connected to a row selection line 271.

When the transfer transistor 221 is turned on, the charge accumulated in the photodiode 211 is transferred to the floating diffusion 260. Then, when the selection transistor 263 is turned on, the source potential of the drive transistor 262 changes according to the potential of the floating diffusion 260. Then, the source potential of the drive transistor 262 is applied to the vertical signal line 270 via the selection transistor 263 and transmitted as an output signal Vout via the vertical signal line 270. Furthermore, when the reset transistor 261 is turned on, the charge accumulated in the floating diffusion 260 is discharged.

Hereinafter, a pixel layout and a cross-sectional structure according to the embodiment will be described taking a 1-pixel-1-cell structure as an example. Note that a back-illuminated CMOS image sensor is taken as an example in the following description.

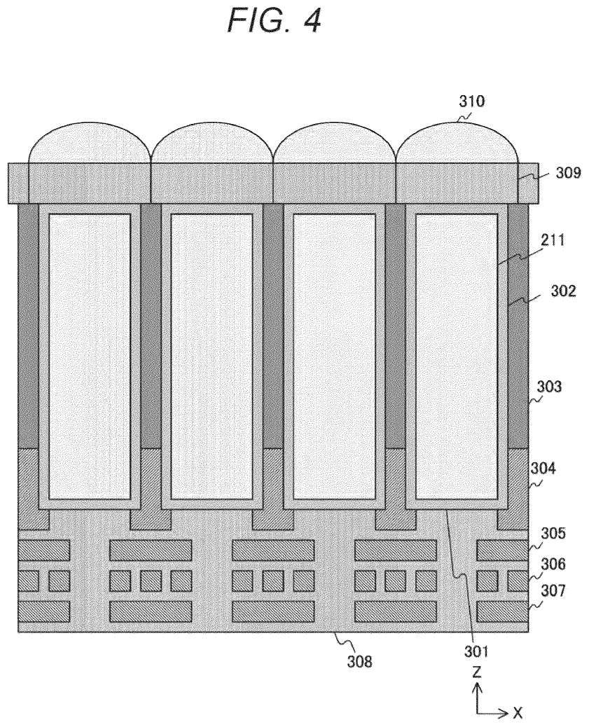

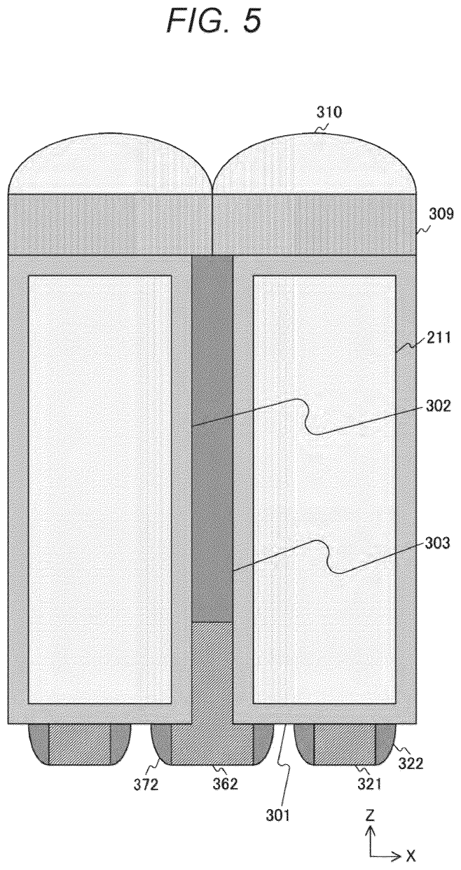

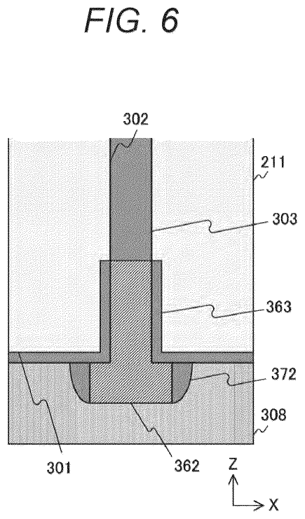

FIG. 4 is a cross-sectional view illustrating a configuration example of pixels according to the first embodiment, FIG. 5 is a cross-sectional view illustrating the configuration example of pixels according to the first embodiment in an enlarged manner, and FIG. 6 is a cross-sectional view illustrating the configuration example of pixels according to the first embodiment in a further enlarged manner.

In FIGS. 4 to 6, the photodiode 211 is formed for each pixel 201 in a semiconductor substrate 301. In addition, a trench 302 for isolating the pixel 201 is formed in the semiconductor substrate 301. As the semiconductor substrate 301, for example, a single crystal silicon substrate can be used. The semiconductor substrate 301 may be a group III-V substrate such as GaAs. At this time, the photodiode 211 is isolated for each pixel 201 by the trench 302. The trench 302 can be formed from the front surface side to the back surface side of the semiconductor substrate 301 so as to penetrate the semiconductor substrate 301 in the thickness direction.

An insulating layer 303 is embedded in the trench 302. The pixel isolation region in which the insulating layer 303 is embedded in the trench 302 can be used as a full-thickness front deep trench isolation (FFTI). The insulating layer 303 can be formed by sub atmospheric-chemical vapor deposition (SA-CVD). A silicon oxide film can be used, for example, as the insulating layer 303. P-type impurities may be injected to the side surface of the trench 302 in which the insulating layer 303 is embedded to form a depletion layer or a pinning layer on the side surface of the trench 302.

In addition, a part of a gate electrode 304 is embedded in a part of the trench 302 in the depth direction Z. At this time, the insulating layer 303 can be removed in a region where the gate electrode 304 is embedded in the trench 302. Polycrystalline silicon into which impurities are introduced can be used, for example, as a material of the gate electrode 304. At this time, in the trench 302, the gate electrode 304 is located on the insulating layer 303. The gate electrode 304 can be used for a pixel transistor. At this time, the gate electrode 304 can form a channel region in a direction intersecting the depth direction Z of the trench 302 along the side surface of the trench 302. In addition, at least a part of the gate electrode 304 of the pixel transistor is located in the trench 302. Furthermore, at least one of the source, the drain, or the floating diffusion of the pixel transistor can be located on the side surface of the trench 302. The direction intersecting the depth direction of the trench 302 can include at least one of the column direction Y or the row direction X.

Furthermore, on the surface of the semiconductor substrate 301, the remaining part of the gate electrode 304 is located on the pixel 201. The “on the pixel 201” mentioned here is “on the side opposite to the light-receiving surface” in the case of a back-illuminated image sensor, and is “on the light-receiving surface side” in the case of a front-illuminated image sensor.

The pixel transistor includes at least one of the transfer transistor 221, the reset transistor 261, the drive transistor 262, or the selection transistor 263 in FIG. 3. At this time, the gate electrode 304 in FIG. 4 may be used as a gate electrode of the transfer transistor 221 or may be used as a gate electrode of the reset transistor 261. Alternatively, the gate electrode 304 in FIG. 4 may be used as a gate electrode of the drive transistor 262, or may be used as a gate electrode of the selection transistor 263.

For example, as illustrated in FIGS. 5 and 6, the gate electrode 304 can be used as a gate electrode 362 of the drive transistor 262. At this time, on the surface of the semiconductor substrate 301, a sidewall 372 is formed on the side wall of the gate electrode 362. Furthermore, in the trench 302, the gate electrode 362 is located on the side surface of the trench 302 with a gate insulating film 363 interposed therebetween, as illustrated in FIG. 6. At this time, the channel region of the drive transistor 262 is formed on the side surface of the trench 302 so that the current flows in the column direction Y.

Here, as illustrated in FIG. 5, a gate electrode 321 of the transfer transistor 221 may be located on the surface of the semiconductor substrate 301. At this time, on the surface of the semiconductor substrate 301, a sidewall 322 is formed on the side wall of the gate electrode 321. A silicon oxide film can be used, for example, as a material of the gate insulating film 363. A silicon oxide film or a silicon nitride film can be used, for example, as a material of the sidewalls 322 and 372.

An insulating layer 308 is formed on the semiconductor substrate 301 so as to cover the gate electrode 362. A silicon oxide film can be used, for example, as the insulating layer 308. As illustrated in FIG. 4, wiring lines 305 to 307 for three layers may be provided in the insulating layer 308. Metal such as aluminum or copper can be used, for example, as a material of the wiring lines 305 to 307.

On the other hand, a color filter 309 is formed for each pixel 201 on the back surface side of the semiconductor substrate 301, and a microlens 310 is formed for each pixel 201 on the color filter 309. A transparent resin such as an acrylic or polycarbonate resin can be used, for example, as a material of the color filter 309 and the microlens 310.

As described above, in the above-described first embodiment, the channel region of the pixel transistor is formed on the side surface of the trench 302 so that the current flows in the direction intersecting the depth direction Z of the trench 302. As a result, the pixel transistor can be disposed along the trench 302 while the gate electrode 304 is disposed in the trench 302. Therefore, it is possible to reduce the area occupied by the pixel transistor in the pixel region while suppressing deterioration in characteristics of the pixel transistor due to miniaturization of the pixel, and it is possible to increase the resolution of the image while suppressing deterioration in image quality.

Furthermore, by embedding at least a part of the gate electrode 304 of the pixel transistor in the trench 302, it is possible to increase the gate width in the depth direction Z of the trench 302 while disposing the pixel transistor along the trench 302. Therefore, it is possible to improve the driving force of the pixel transistor while suppressing an increase in the area occupied by the pixel transistor in the pixel region.

### 2. Second Embodiment

In the first embodiment described above, the gate electrode 362 is provided in the trench 302 and on the pixel with the gate insulating film 363 interposed therebetween. In a second embodiment, a gate electrode 341 is provided in the trench 302 with the gate insulating film 363 interposed therebetween and, at the same time, the gate electrode 341 is provided on the pixel with a spacer insulating layer 311 on the gate insulating film 363 interposed therebetween.

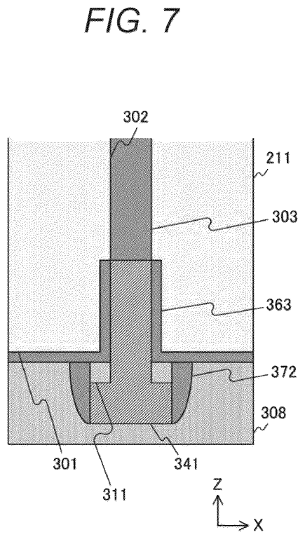

FIG. 7 is a cross-sectional view illustrating a configuration example of pixels according to the second embodiment.

In the configuration of the second embodiment in FIG. 7, the spacer insulating layer 311 is included additionally to the configuration of the first embodiment described above. Other configurations of the pixels of the second embodiment are similar to those of the pixels of the first embodiment described above. The spacer insulating layer 311 is located under the gate electrode 341 on the pixel 201. A silicon oxide film or a silicon nitride film can be used, for example, as a material of the spacer insulating layer 311.

As described above, in the second embodiment, the spacer insulating layer 311 is provided under the gate electrode 341 on the pixel 201. As a result, the corner of the gate electrode 341 located on the pixel 201 can be kept away from the pixel 201, and the influence of the electric field at the corner of the gate electrode 341 can be alleviated.

### 3. Third Embodiment

In the first embodiment described above, the pixel isolation region where the pixel transistor is provided is configured by the FFTI. In a third embodiment, the pixel isolation region where the pixel transistor is provided is configured by the FDTI and the RDTI.

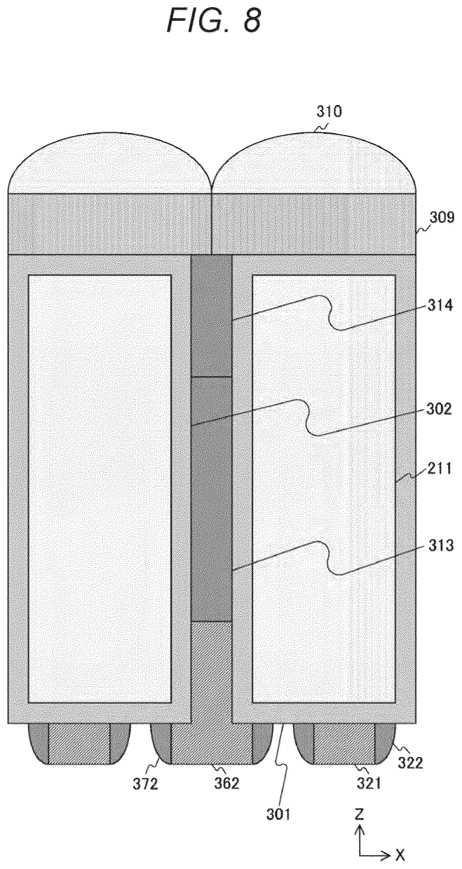

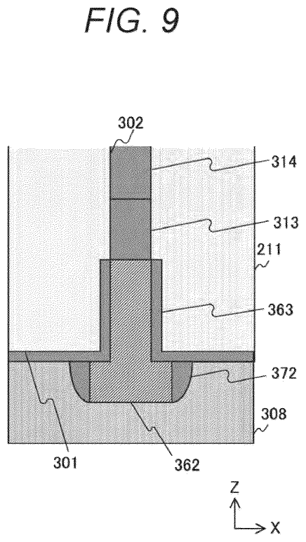

FIG. 8 is a cross-sectional view illustrating a configuration example of pixels according to the third embodiment, and FIG. 9 is a cross-sectional view illustrating the configuration example of pixels according to the third embodiment in an enlarged manner.

In the configuration of the third embodiment in FIGS. 8 and 9, insulating layers 313 and 314 are provided instead of the insulating layer 303 of the first embodiment described above. Other configurations of the pixels of the third embodiment are similar to those of the pixels of the first embodiment described above. The insulating layers 313 and 314 are embedded in a part of the trench 302 in the depth direction Z. At this time, the insulating layer 314 is located on the back surface side of the semiconductor substrate 301 in the depth direction Z of the trench 302. The insulating layer 313 is located between the gate electrode 341 and the insulating layer 314 in the depth direction Z of the trench 302. The pixel isolation region in which the insulating layer 313 is embedded in the trench 302 can be used as the FDTI. The pixel isolation region in which the insulating layer 314 is embedded in the trench 302 can be used as the RDTI. A silicon oxide film can be used, for example, as the insulating layers 313 and 314.

As described above, according to the third embodiment, since the pixel isolation region is configured by the FDTI and the RDTI, the side surface of the trench 302 can be exposed on the back surface side of the semiconductor substrate 301 before the insulating layer 314 is embedded in the trench 302. This allows impurities to be introduced from the back surface side of the semiconductor substrate 301 to the side surface of the trench 302 before the insulating layer 314 is embedded in the trench 302, and therefore pixel isolation properties can be improved.

### 4. Fourth Embodiment

In the first embodiment described above, the pixel isolation region where the pixel transistor is provided is configured by the FFTI, and the gate electrode 362 is provided in the trench 302 and on the pixel with the gate insulating film 363 interposed therebetween. In a fourth embodiment, the pixel isolation region where the pixel transistor is provided is configured by the FDTI and the RDTI and, on the pixel, the gate electrode 341 is provided with the spacer insulating layer 311 on the gate insulating film 363 interposed.

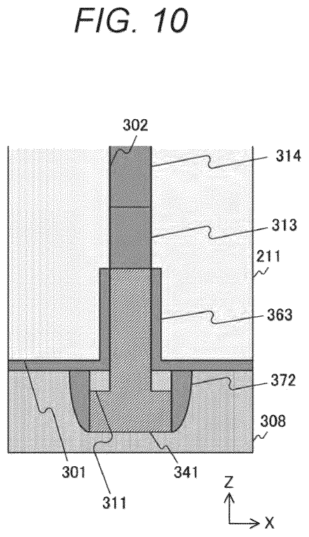

FIG. 10 is a cross-sectional view illustrating a configuration example of pixels according to the fourth embodiment.

In the configuration of the fourth embodiment in FIG. 10, the spacer insulating layer 311 of the second embodiment is included additionally to the configuration of the third embodiment described above. Other configurations of the pixels of the fourth embodiment are similar to those of the pixels of the third embodiment described above.

As described above, in the above-described fourth embodiment, the pixel isolation region where the pixel transistor is provided is configured by the FDTI and the RDTI, and the spacer insulating layer 311 is provided under the gate electrode 341 on the pixel 201. As a result, the corner of the gate electrode 341 located on the pixel 201 can be kept away from the pixel 201, and the influence of the electric field at the corner of the gate electrode 341 can be alleviated and, at the same time, pixel isolation properties can be improved.

Hereinafter, circuits, layouts, and cross-sectional structures of cells according to embodiments will be described by taking a 4-pixel-1-cell structure in which four pixels are arranged per cell in a matrix as an example. Note that a back-illuminated image sensor is taken as an example in the following description. The 4-pixel-1-cell structure may be used for the Bayer array or the quad-Bayer array.

### 5. Fifth Embodiment

In the first embodiment described above, the pixel transistor is provided in the trench in the 1-pixel-1-cell structure. In a fifth embodiment, pixel transistors are provided in a trench 502 in the 4-pixel-1-cell structure.

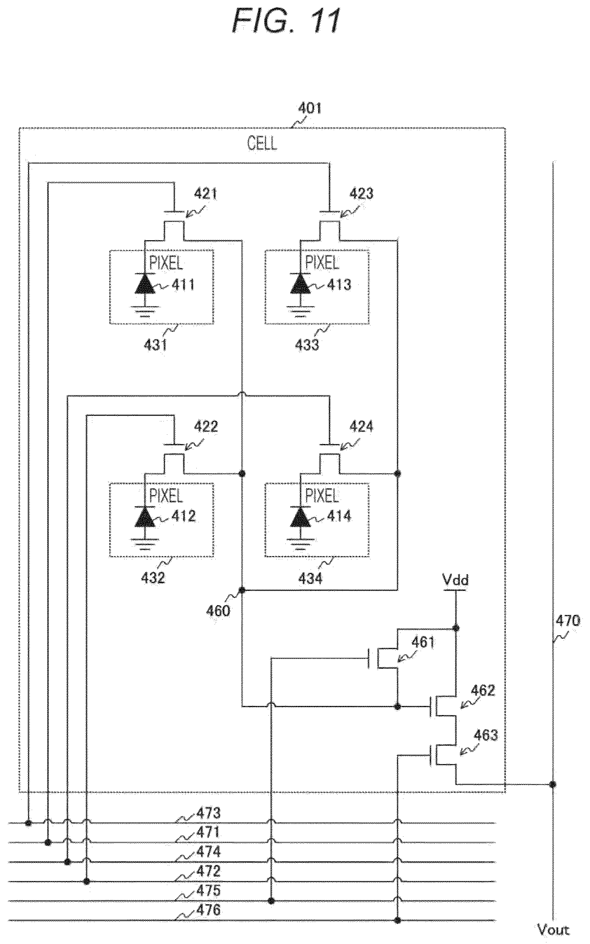

FIG. 11 is a diagram illustrating a circuit configuration example of pixels according to the fifth embodiment.

In FIG. 11, a cell 401 includes pixels 431 to 434. In addition, the cell 500 includes transfer transistors 421 to 424, a reset transistor 461, a drive transistor 462, a selection transistor 463, and a floating diffusion 460. The pixels 431 to 434 include photodiodes 411 to 414, respectively.

The drive transistor 462 and the selection transistor 463 are connected in series. Cathodes of the respective photodiodes 411 to 414 are connected to the floating diffusion 460 via the transfer transistors 421 to 424, respectively. In addition, the floating diffusion 460 is connected to a power supply Vdd via the reset transistor 461. Furthermore, the power supply Vdd is connected to a vertical signal line 470 via the series circuit of the drive transistor 462 and the selection transistor 463. A gate electrode of the drive transistor 462 is connected to the floating diffusion 460. Gate electrodes of the transfer transistors 421 to 424 are connected to pixel selection lines 471 to 474, respectively, a gate electrode of the reset transistor 461 is connected to a reset line 475, and a gate electrode of the selection transistor 463 is connected to a row selection line 476.

When the transfer transistors 421 to 424 are turned on, the charges accumulated in the photodiodes 411 to 414, respectively, are transferred to the floating diffusion 460. Then, when the selection transistor 463 is turned on, the source potential of the drive transistor 462 changes according to the potential of the floating diffusion 460. Then, the source potential of the drive transistor 462 is applied to the vertical signal line 470 via the selection transistor 463 and transmitted as an output signal Vout via the vertical signal line 470. Furthermore, when the reset transistor 461 is turned on, the charge accumulated in the floating diffusion 460 is discharged.

In the 4-pixel-1-cell structure, the reset transistor 461, the drive transistor 462, the selection transistor 463, and the floating diffusion 460 can be shared by the four pixels 431 to 434, and the pixel region can be enlarged as compared with the configuration of FIG. 3.

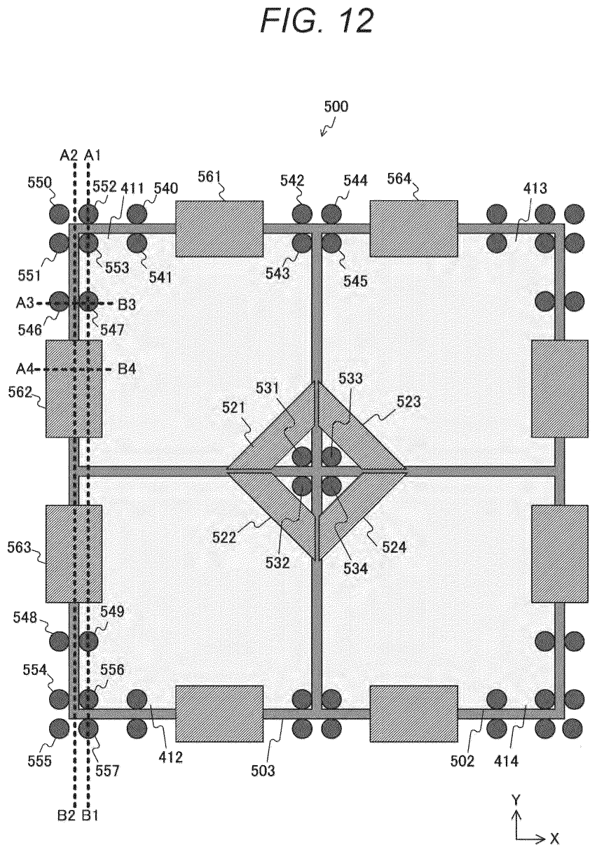

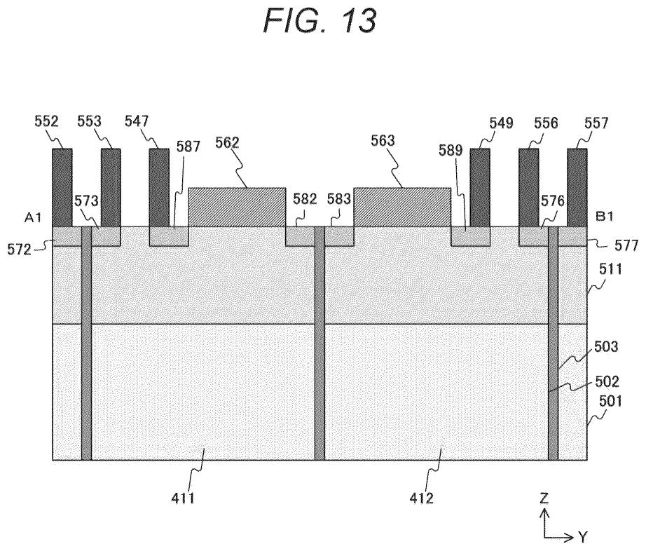

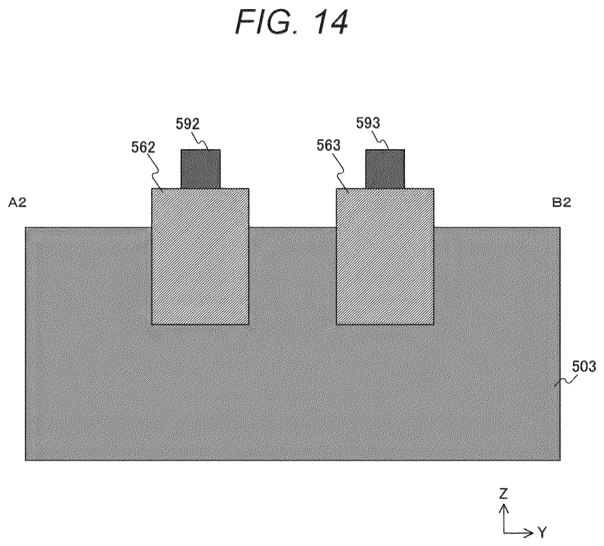

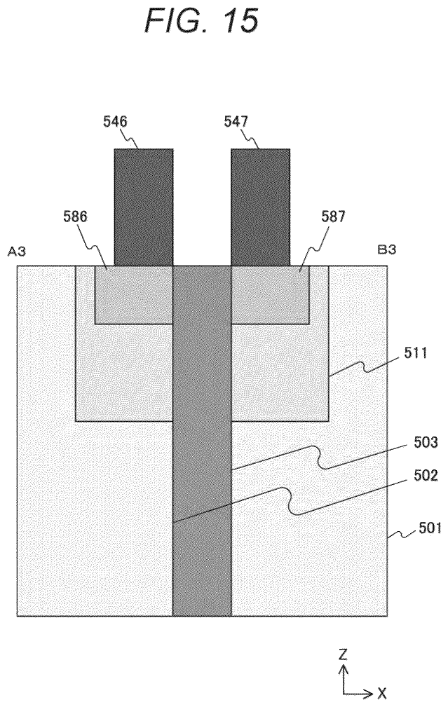

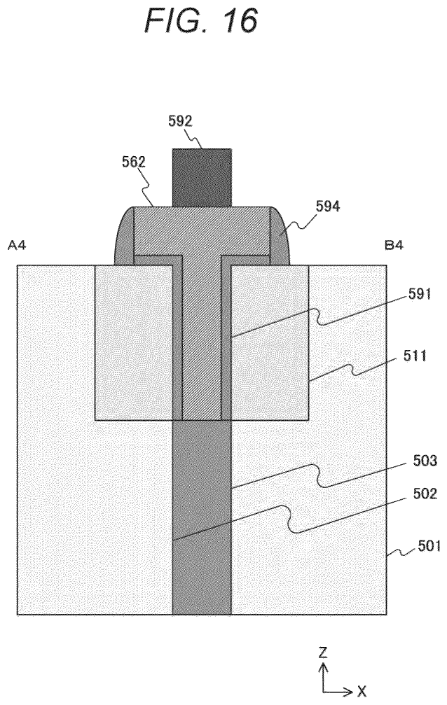

FIG. 12 is a plan view illustrating a configuration example of the cell according to the fifth embodiment. FIG. 13 is a cross-sectional view of a configuration example taken along line A1-B1 of the configuration example of the cell according to the fifth embodiment. FIG. 14 is a cross-sectional view of a configuration example taken along line A2-B2 of the configuration example of the cell according to the fifth embodiment. FIG. 15 is a cross-sectional view of a configuration example taken along line A3-B3 of the configuration example of the cell according to the fifth embodiment. FIG. 16 is a cross-sectional view of a configuration example taken along line A4-B4 of the configuration example of the cell according to the fifth embodiment. Note that contact plugs 592 and 593 in FIG. 14 are omitted in FIG. 12.

In FIGS. 12 to 16, a cell 500 includes the pixels 431 to 434. On a semiconductor substrate 501, the photodiodes 411 to 414 are formed for the respective pixels 431 to 434. Furthermore, the trench 502 for isolating each of the pixels 431 to 434 is formed in the semiconductor substrate 501. A single crystal silicon substrate can be used, for example, as the semiconductor substrate 501. At this time, the photodiodes 411 to 414 are isolated for the respective pixels 431 to 434 by the trench 502. The trench 502 can be formed from the front surface side to the back surface side of the semiconductor substrate 501 so as to penetrate the semiconductor substrate 501 in the thickness direction.

An insulating layer 503 is embedded in the trench 502. The pixel isolation region in which the insulating layer 503 is embedded in the trench 502 can be used as the FFTI. A silicon oxide film can be used, for example, as the insulating layer 503.

In addition, a P well 511 is formed in the semiconductor substrate 501, and P⁺ impurity diffusion layers 572, 573, 576, and 577 used for contact with the P well 511 are formed in the P well 511, as illustrated in FIG. 13, for example. The P⁺ impurity diffusion layers 572, 573, 576, and 577 are each isolated by the trench 502 between the pixels adjacent to each other. The P⁺ impurity diffusion layers 572, 573, 576, and 577 can be disposed at the four corners of the cell 500.

Furthermore, contact plugs 550 to 557 isolated for respective pixels are disposed at the four corners of the cell 500. In addition, as illustrated in FIG. 13, for example, the contact plugs 552, 553, 556, and 557 are connected to the P⁺ impurity diffusion layers 572, 573, 576, and 577, respectively. The P⁺ impurity diffusion layers each isolated by the trench 502 can be connected by wiring lines via the contact plugs 550 to 557. The wiring line 305 in FIG. 4 can be used, for example, as the wiring lines connecting the contact plugs 550 to 557.

Furthermore, as illustrated in FIGS. 13 and 15, for example, N⁺ impurity diffusion layers 582, 583, 586, 587, and 589 used as sources or drains of the pixel transistors are formed in the P well 511. The N⁺ impurity diffusion layers 582, 583, 586, 587, and 589 are each isolated by the trench 502 between the pixels adjacent to each other. The N⁺ impurity diffusion layers 582, 583, 586, 587, and 589 are disposed along the trench 502. At this time, the N⁺ impurity diffusion layers can be disposed so as to face each other with the trench 502 interposed between the pixels adjacent to each other. For example, as illustrated in FIG. 13, the N⁺ impurity diffusion layers 582 and 583 can be disposed to face each other with the trench 502 interposed therebetween, and as illustrated in FIG. 15, the N⁺ impurity diffusion layers 586 and 587 can be disposed to face each other with the trench 502 interposed therebetween.

Furthermore, contact plugs 540 to 549 are disposed in an isolated manner along the trench 502 in the cell 500. In addition, as illustrated in FIGS. 13 and 15, for example, the contact plugs 546, 547, and 549 are connected to the N⁺ impurity diffusion layers 586, 587, and 589, respectively. The N⁺ impurity diffusion layers each isolated so as to face each other with the trench 502 interposed therebetween can be connected by wiring lines via the contact plugs 540 to 549, respectively. The wiring line 305 in FIG. 4 can be used, for example, as the wiring lines connecting the contact plugs 540 to 549.

In addition, + impurity diffusion layers used as floating diffusions are formed so as to be isolated for respective pixels in the P well 511. The + impurity diffusion layers used as the floating diffusions can be disposed at corners of respective pixels so as to face each other with the trench 502 interposed therebetween. Contact plugs 531 to 534 are disposed so as to be isolated on the N⁺ impurity diffusion layers formed so as to be isolated for respective pixels as the floating diffusions. Tungsten can be used, for example, as a material of the contact plugs 531 to 534, 540 to 549, and 550 to 557.

In addition, gate electrodes 521 to 524 and 561 to 564 are disposed in the cell 500. The gate electrodes 521 to 524 are disposed on the pixels so as to be isolated around the contact plugs 531 to 534. At this time, the ends in the width direction of the gate electrodes 521 to 524 are disposed on the insulating layer 503 embedded in the trench 502.

The gate electrodes 561 to 564 are disposed so as to be isolated on the trench 502. At this time, a part of each of the gate electrodes 561 to 564 can be disposed to protrude on the pixels. The gate electrodes 561 to 563 can be used for the reset transistor 461, the drive transistor 462, and the selection transistor 463 in FIG. 11. The gate electrode 561 is disposed between the contact plugs 540 and 541 and the contact plugs 542 and 543. The gate electrode 562 is disposed so as to be adjacent to the contact plugs 546 and 547. The gate electrode 563 is disposed so as to be adjacent to the contact plugs 548 and 549. Furthermore, the gate electrodes 562 and 563 are disposed so as to be adjacent to each other.

The gate electrode 564 can be used as a dummy electrode. By providing the cell 500 with the dummy electrode, the symmetry of the element layout can be improved, and manufacturing variations among pixels can be reduced. Note that the dummy electrode may be omitted. Polycrystalline silicon can be used, for example, as a material of the gate electrodes 521 to 524 and 561 to 564.

In addition, parts of the gate electrodes 561 to 564 are embedded in a part of the trench 502 in the depth direction Z. Here, the insulating layer 503 can be removed in a region where the gate electrodes 561 to 564 are embedded in the trench 502. At this time, in the trench 502, the gate electrodes 561 to 564 are located on the insulating layer 503. Here, each of the gate electrodes 561 to 564 can form a channel region on the side surface of the trench 502 so that a current flows in a direction intersecting the depth direction Z of the trench 502. Furthermore, the N⁺ impurity diffusion layer used as the source, the drain, or the floating diffusion of the pixel transistor can be located on the side surface of the trench 502. At this time, in the trench 502, the gate electrodes 561 to 564 can be disposed at positions deeper than the N⁺ impurity diffusion layer used as the source, the drain, or the floating diffusion of the pixel transistor. The direction intersecting the depth direction of the trench 502 can include at least one of the column direction Y or the row direction X. For example, the reset transistor 461 can be disposed along the row direction X, and the drive transistor 462 and the selection transistor 463 can be disposed along the column direction Y.

In addition, a contact plug is disposed on each of the gate electrodes 521 to 524 and 561 to 564. For example, as illustrated in FIGS. 14 and 16, the contact plug 592 is disposed on the gate electrode 562, and the contact plug 593 is disposed on the gate electrode 563.

In addition, a sidewall is formed on the side wall of each of the gate electrodes 521 to 524 and 561 to 564 on the surface of the semiconductor substrate 501. For example, as illustrated in FIG. 16, a sidewall 594 is formed on the side wall of the gate electrode 562. Furthermore, in the trench 502, each of the gate electrodes 561 to 564 is located on the side surface of the trench 502 with a gate insulating film interposed therebetween. For example, in the trench 502, the gate electrode 562 is located on the side surface of the trench 502 with a gate insulating film 591 interposed therebetween, as illustrated in FIG. 16. A silicon oxide film can be used, for example, as a material of the gate insulating film 591. A silicon oxide film or a silicon nitride film can be used, for example, as a material of the sidewall 594.

As described above, in the above-described fifth embodiment, the channel region of the pixel transistor is formed on the side surface of the trench 502 so that the current flows in the direction intersecting the depth direction Z of the trench 502. As a result, the pixel transistors can be disposed along the trench 502 while the respective gate electrodes 561 to 564 are disposed in the trench 502. Therefore, it is possible to reduce the area occupied by the pixel transistor in the pixel region while suppressing deterioration in characteristics of the pixel transistor due to miniaturization of the pixel, and it is possible to increase the resolution of the image while suppressing deterioration in image quality.

Furthermore, by embedding at least a part of each of the gate electrodes 561 to 564 in the trench 502, it is possible to increase the gate width in the depth direction Z of the trench 502 while disposing the pixel transistors along the trench 502. Therefore, it is possible to improve the driving force of the pixel transistor while suppressing an increase in the area occupied by the pixel transistor in the pixel region.

In addition, by locating a part of each of the gate electrodes 561 to 564 so as to protrude on the pixels, it is possible to secure the contact area of each of the gate electrodes 561 to 564 while embedding a part of each of the gate electrodes 561 to 564 in the trench 502.

In addition, by isolating each of the N⁺ impurity diffusion layers of the pixels adjacent to each other by the trench 502, it is not necessary to connect respective ones of the sources, the drains, and the floating diffusions of the pixels adjacent to each other in the trench 502, and the number of processes can be reduced.

### 6. Sixth Embodiment

In the above-described fifth embodiment, the contact plugs 531 to 534, 540 to 549, and 550 to 557 individually connected to the impurity diffusion layers of the pixel transistors each isolated by the pixel isolation region are provided. In a sixth embodiment, contact plugs 630, 640 to 643, 650, and 651 connected in common with the impurity diffusion layers of the pixel transistors each isolated by the pixel isolation region are provided.

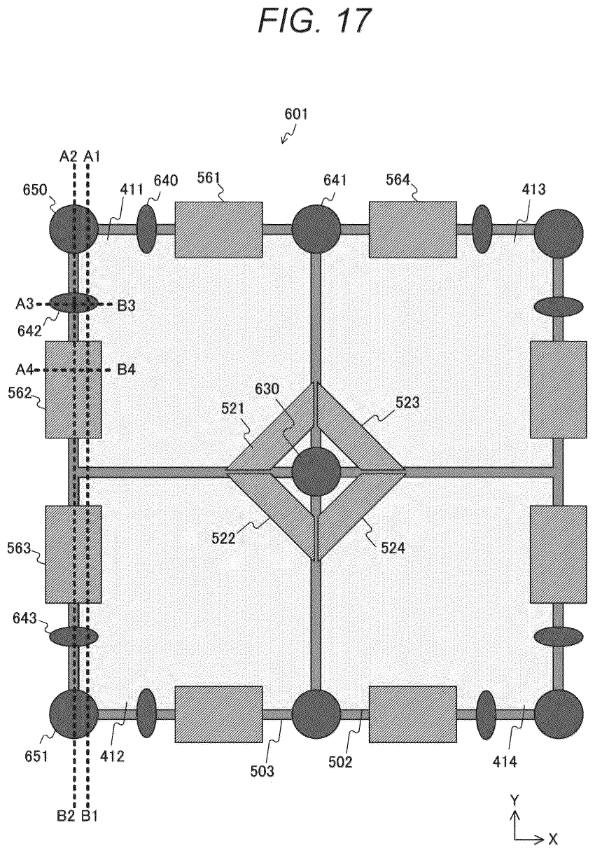

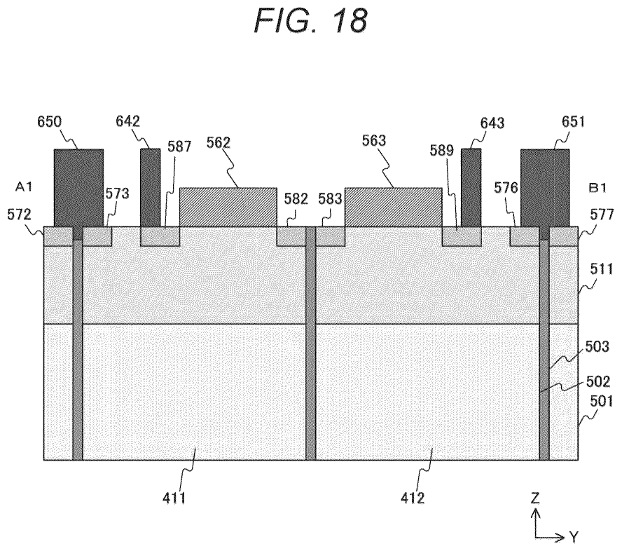

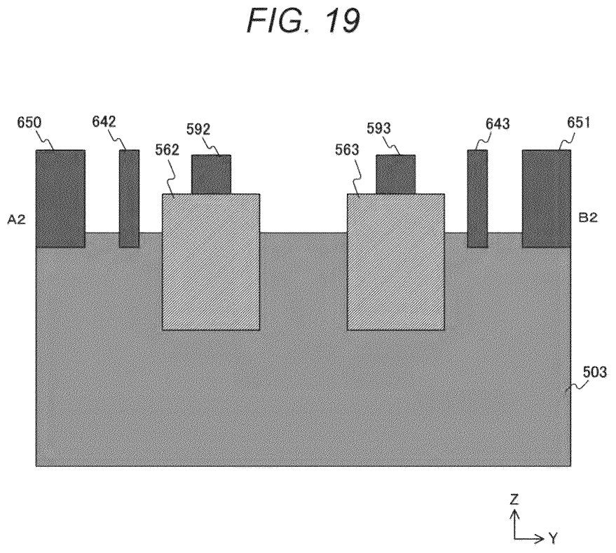

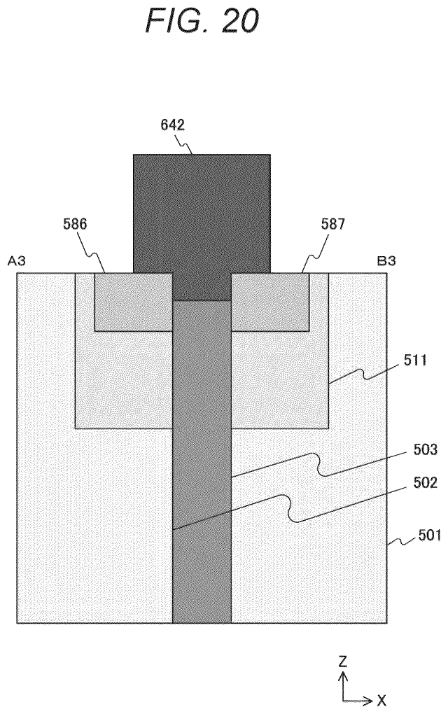

FIG. 17 is a plan view illustrating a configuration example of a cell according to the sixth embodiment. FIG. 18 is a cross-sectional view of a configuration example taken along line A1-B1 of the configuration example of the cell according to the sixth embodiment. FIG. 19 is a cross-sectional view of a configuration example taken along line A2-B2 of the configuration example of the cell according to the sixth embodiment. FIG. 20 is a cross-sectional view of a configuration example taken along line A3-B3 of the configuration example of the cell according to the sixth embodiment. Note that the configuration of the cell taken along line A4-B4 of FIG. 17 is similar to the configuration of the cell taken along line A4-B4 of FIG. 12.

In the configuration of the sixth embodiment in FIGS. 17 to 20, a cell 601 is provided instead of the cell 500 of the above-described fifth embodiment. The cell 601 is provided with the contact plugs 630, 640 to 643, 650, and 651 instead of the contact plugs 531 to 534, 540 to 549, and 550 to 553 of the above-described fifth embodiment. Other configurations of the cell of the sixth embodiment are similar to those of the cell of the fifth embodiment described above.

The contact plugs 630, 640 to 643, 650, and 651 are disposed on the trench 502 along the trench 502. At this time, each of the contact plugs 630, 640 to 643, 650, and 651 is disposed to protrude on the pixels.

The respective contact plugs 650 and 651 are disposed at four corners of the cell 601 in common with four pixels adjacent to each other. In addition, each of the contact plugs 650 and 651 is connected across the trench 502 to the P⁺ impurity diffusion layers each isolated by the trench 502. For example, as illustrated in FIG. 18, the contact plug 650 is connected to the P⁺ impurity diffusion layers 572 and 573 across the trench 502, and the contact plug 651 is connected to the P⁺ impurity diffusion layers 576 and 577 across the trench 502.

In addition, the contact plugs 640 to 643 are disposed in an isolated manner along the trench 502. Furthermore, each of the contact plugs 640 to 643 is connected across the trench 502 to the N⁺ impurity diffusion layers disposed so as to face each other with the trench 502 interposed therebetween. For example, as illustrated in FIG. 20, the contact plug 642 is connected to the N⁺ impurity diffusion layers 586 and 587 across the trench 502.

In addition, the contact plug 630 is disposed at a position surrounded by the gate electrodes 521 to 524. Furthermore, the contact plug 630 is connected to the N⁺ impurity diffusion layers formed so as to be isolated for respective pixels as the floating diffusions.

As described above, in the above-described sixth embodiment, the impurity diffusion layers facing each other with the trench 502 interposed therebetween are connected across the trench 502 by each of the contact plugs 630, 640 to 643, 650, and 651. As a result, it is possible to increase the connection area between the respective contact plugs 630, 640 to 643, 650, and 651 and the wiring lines while suppressing an increase in the number of processes.

### 7. Seventh Embodiment

In the above-described sixth embodiment, the contact plugs 630, 640 to 643, 650, and 651 connected in common with the impurity diffusion layers of the pixel transistors each isolated by the pixel isolation region are provided. In a seventh embodiment, base layers 730, 740 to 744, 750, and 751 including the same material as that of the gate electrodes of the pixel transistors are provided on the impurity diffusion layers of the pixel transistors.

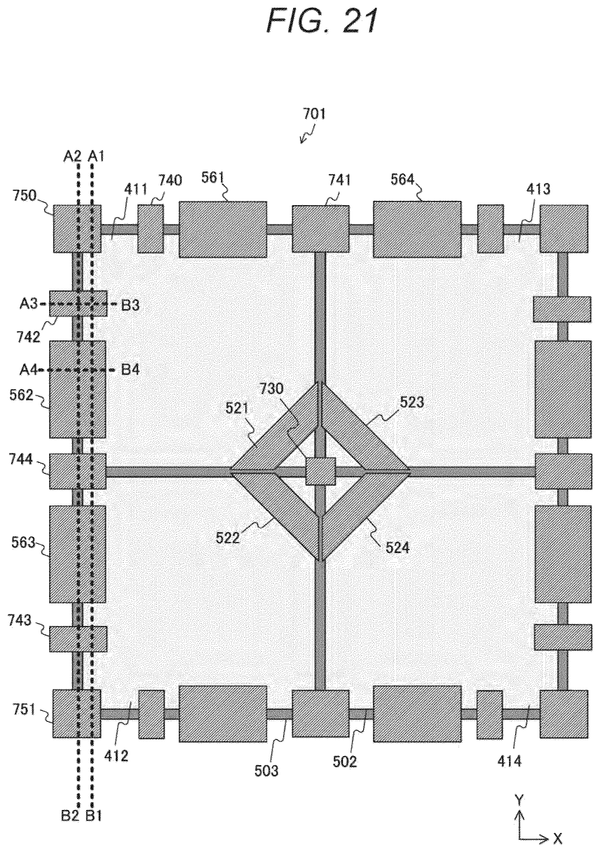

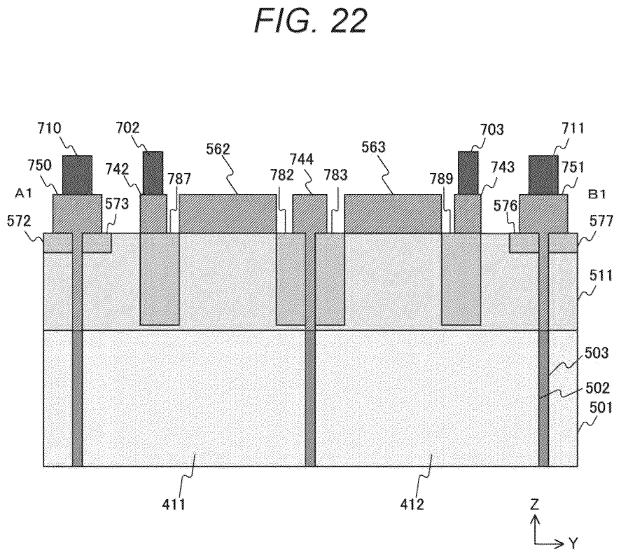

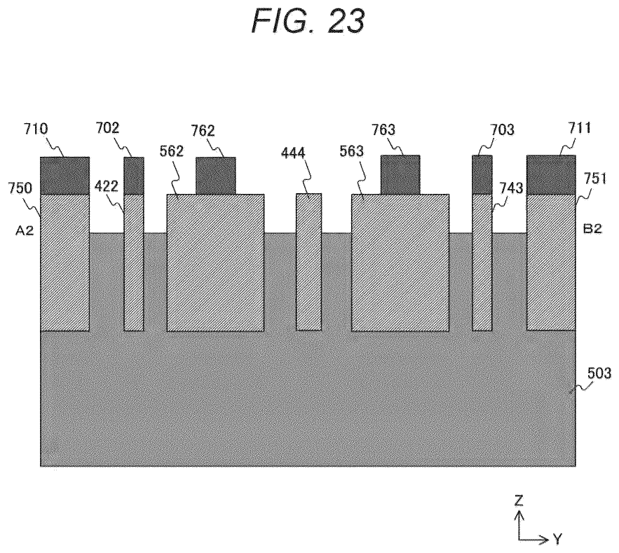

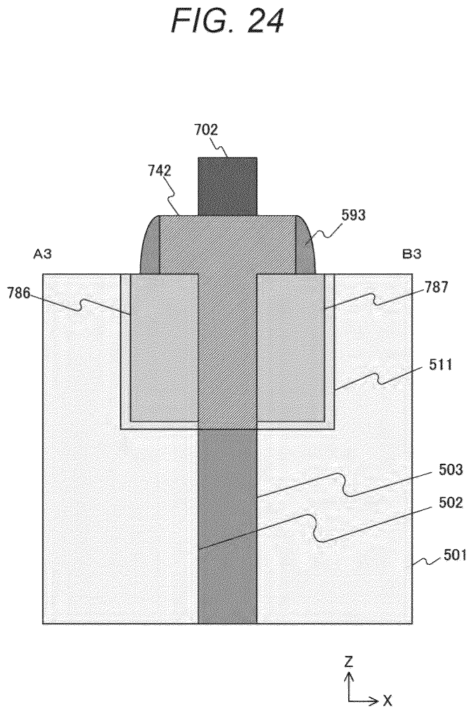

FIG. 21 is a plan view illustrating a configuration example of a cell according to the seventh embodiment. FIG. 22 is a cross-sectional view of a configuration example taken along line A1-B1 of the configuration example of the cell according to the seventh embodiment. FIG. 23 is a cross-sectional view of a configuration example taken along line A2-B2 of the configuration example of the cell according to the seventh embodiment. FIG. 24 is a cross-sectional view of a configuration example taken along line A3-B3 of the configuration example of the cell according to the seventh embodiment. Note that the configuration taken along line A4-B4 of FIG. 21 is similar to the configuration of the cell taken along line A4-B4 of FIG. 12.

In the configuration of the seventh embodiment in FIGS. 21 to 24, a cell 701 is provided instead of the cell 601 of the above-described sixth embodiment. The cell 701 is provided with the base layers 730, 740 to 744, 750, and 751 instead of the contact plugs 630, 640 to 643, 650, and 651 of the above-described sixth embodiment. In addition, a contact plug is provided on each of the base layers 730, 740 to 744, 750, and 751.

The base layers 730, 740 to 744, 750, and 751 are disposed on the trench 502 along the trench 502. At this time, each of the base layers 730, 740 to 744, 750, and 751 is disposed to protrude on the pixels. Each of the base layers 730, 740 to 744, 750, and 751 can include the same material as that of the gate electrodes 561 to 564. For example, polycrystalline silicon into which impurities are introduced can be used as a material of each of the base layers 730, 740 to 744, 750, and 751.

In addition, parts of the base layers 740 to 744, 750, and 751 are embedded in a part of the trench 502 in the depth direction Z. Here, the insulating layer 503 can be removed in a region where the base layers 740 to 744, 750, and 751 are embedded in the trench 502. At this time, in the trench 502, the base layers 740 to 744, 750, and 751 are located on the insulating layer 503. In the trench 502, the position of each of the base layers 740 to 744, 750, and 751 in the depth direction Z can be equal to the position of each of the gate electrodes 561 to 564 in the depth direction Z.

The depth of the N⁺ impurity diffusion layer used as the source or drain of the pixel transistor can be increased in accordance with the position in the depth direction Z of the base layers 740 to 744 in the trench 502. For example, as illustrated in FIGS. 22 and 24, N⁺ impurity diffusion layers 782, 783, 786, 787, and 789 can be provided instead of the N⁺ impurity diffusion layers 582, 583, 586, 587, and 589 of FIGS. 18 and 20. The depth of the N⁺ impurity diffusion layers 782, 783, 786, 787, and 789 embedded in the trench 502 can be greater than the depth of the N⁺ impurity diffusion layers 582, 583, 586, 587, and 589 embedded in the trench 502. Other configurations of the cell of FIGS. 21 to 24 are similar to those of the cell of FIGS. 17 to 20.

The respective base layers 750 and 751 are disposed at four corners of the cell 701 in common with four pixels adjacent to each other. In addition, each of the base layers 750 and 751 is connected across the trench 502 to the P⁺ impurity diffusion layers each isolated by the trench 502 so as to be adjacent to each other. For example, as illustrated in FIG. 22, the base layer 750 is connected to the P⁺ impurity diffusion layers 572 and 573 across the trench 502, and the base layer 751 is connected to the P⁺ impurity diffusion layers 576 and 577 across the trench 502.

In addition, the base layers 740 to 744 are disposed in an isolated manner along the trench 502. Furthermore, each of the base layers 740 to 744 is connected across the trench 502 to the N⁺ impurity diffusion layers disposed so as to face each other with the trench 502 interposed therebetween. For example, as illustrated in FIG. 24, the base layer 742 is connected to the N⁺ impurity diffusion layers 786 and 787 across the trench 502. Furthermore, a sidewall 593 is formed on the side wall of the base layer 742.

In addition, the base layer 730 is disposed at a position surrounded by the gate electrodes 521 to 524. Furthermore, the base layer 730 is connected to the N⁺ impurity diffusion layers formed so as to be isolated for respective pixels as floating diffusions.

As described above, in the above-described seventh embodiment, the base layers 730, 740 to 744, 750, and 751 to which the contact plugs are connected are provided in the cell 701. This makes it possible to prevent the tip of the contact plug from entering the trench 502 at the time of forming the contact plug, and to form the base layers 730, 740 to 744, 750, and 751 at the time of forming the gate electrodes 561 to 564 of the pixel transistors. Therefore, it is possible to suppress the leakage current while suppressing the increase in the manufacturing processes.

Furthermore, parts of the base layers 740 to 744 are embedded in the trench 502. As a result, the widths in the depth direction Z of the source and the drain in the trench 502 can be enlarged in accordance with the gate widths in the depth direction Z of the gate electrodes 561 to 563 embedded in the trench 502. Therefore, a bypass path of the current flowing between the source and the drain via the channel region on the side surface of the trench 502 can be shortened, and the channel resistance of the pixel transistor can be reduced. As a result, the transconductance of the pixel transistor can be reduced, and noise can be reduced.

In addition, the base layers 730, 740 to 744, 750, and 751 include the same material as that of the gate electrodes 560 to 563. As a result, the gate electrodes 560 to 563 and the base layers 730, 740 to 744, 750, and 751 can be collectively formed on the basis of a photolithography technique and a dry etching technique, and an increase in the number of processes can be suppressed.

### 8. Eighth Embodiment

In the above-described seventh embodiment, the pixel transistor provided in the trench 502 has a single amplifier configuration. In an eighth embodiment, the pixel transistor provided in the trench 502 has a double amplifier configuration.

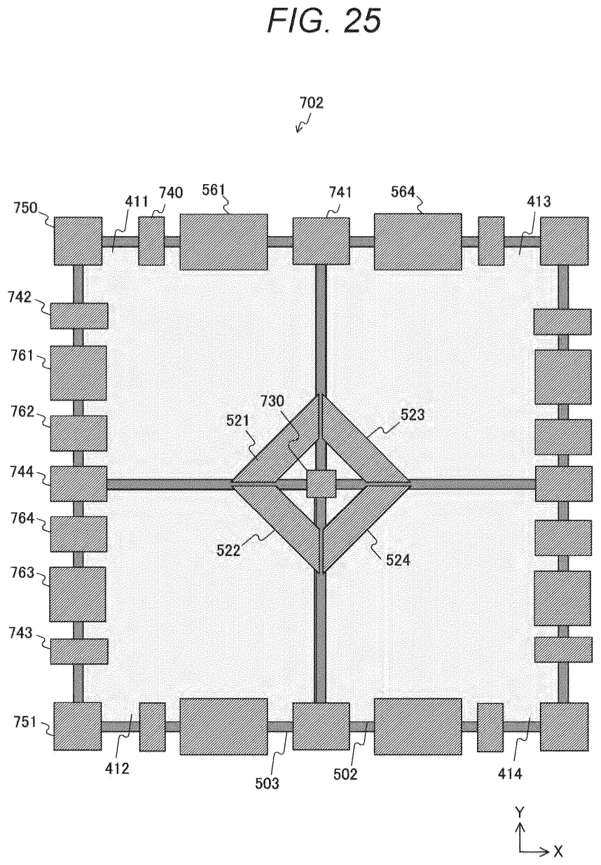

FIG. 25 is a plan view illustrating a configuration example of a cell according to the eighth embodiment.

In the configuration of the eighth embodiment in FIG. 25, a cell 702 is provided instead of the cell 701 of the above-described seventh embodiment. In the cell 702, gate electrodes 761 to 764 are provided instead of the gate electrodes 562 and 563 of the above-described seventh embodiment. In addition, a contact plug is disposed on each of the gate electrodes 761 to 764. Other configurations of the cell of the eighth embodiment are similar to those of the cell of the seventh embodiment described above.

The gate electrodes 761 to 764 are disposed on the trench 502 so as to be isolated along the trench 502. The gate electrodes 761 and 762 can be used for the drive transistor 462. The gate electrodes 763 and 764 can be used for the selection transistor 463. Other configurations of the gate electrodes 761 to 764 in FIG. 25 are similar to those of the gate electrodes 562 and 563 in FIG. 21.

As described above, according to the eighth embodiment, the gate electrodes 761 to 764 instead of the gate electrodes 562 and 563 are provided in the cell 702, and therefore it is possible to achieve the double amplifier configuration while suppressing complication of the manufacturing processes.

### 9. Ninth Embodiment

In the above-described eighth embodiment, in the configuration in which the base layer 730 connected in common with the floating diffusions isolated by the pixel isolation region is provided, the ends in the width direction of the gate electrodes 521 to 524 of the transfer transistors are disposed on the pixel isolation region. In a ninth embodiment, in the configuration in which the contact plug 630 connected in common with the floating diffusions each isolated by the pixel isolation region is provided, the ends in the width direction of the gate electrodes 521 to 524 of the transfer transistors are disposed on the pixel isolation region.

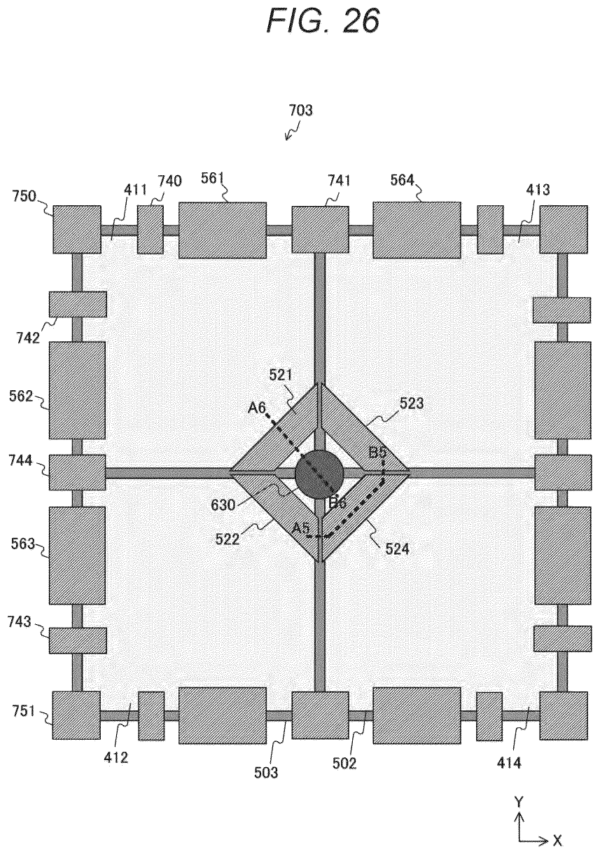

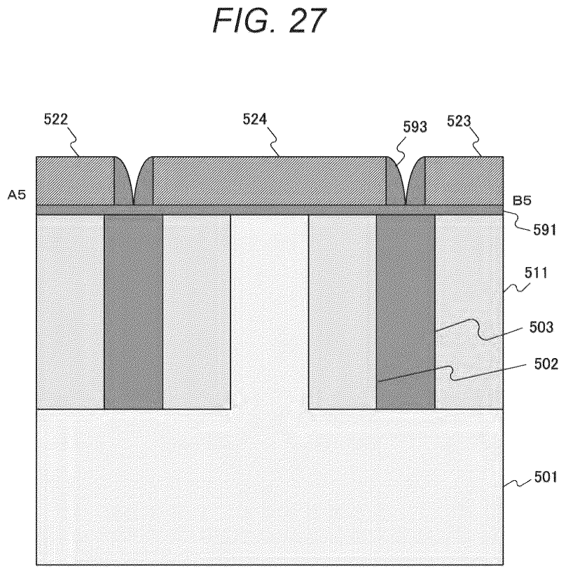

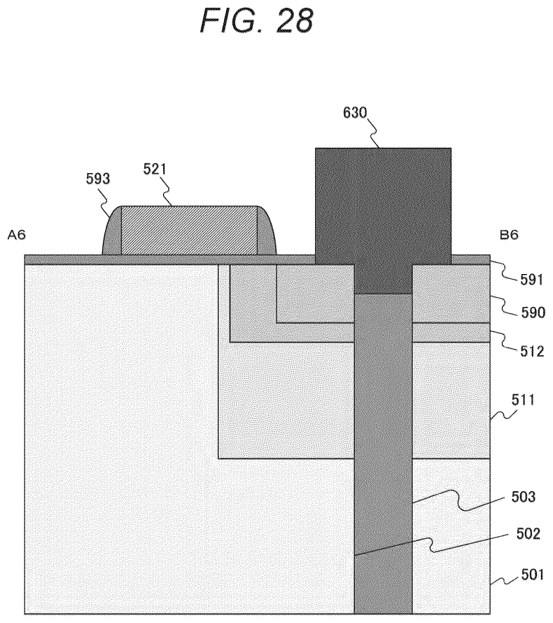

FIG. 26 is a plan view illustrating a configuration example of a cell according to the ninth embodiment. FIG. 27 is a cross-sectional view of a configuration example taken along line A5-B5 of the configuration example of the cell according to the ninth embodiment. FIG. 28 is a cross-sectional view of a configuration example taken along line A6-B6 of the configuration example of the cell according to the ninth embodiment.

In the configuration of the ninth embodiment in FIGS. 26 to 28, a cell 703 is provided instead of the cell 701 of the above-described seventh embodiment. The cell 703 is provided with the contact plug 630 of the above-described sixth embodiment instead of the base layer 730 of the above-described seventh embodiment. Other configurations of the cell of the ninth embodiment are similar to those of the cell of the sixth embodiment described above.

Here, in the cell 703, the transfer transistors 421 to 424 in FIG. 11 have a planar structure. In addition, the ends in the width direction of the gate electrodes 521 to 524 of the transfer transistors 421 to 424 are located on the insulating layer 503 embedded in the trench 502.

In a region surrounded by the gate electrodes 521 to 524, an N well 512 is formed in the P well 511. An N⁺ impurity diffusion layer 590 is formed in the N well 512. On the N⁺ impurity diffusion layer 590, the gate insulating film 591 is removed, and a part of the surface of the N⁺ impurity diffusion layer 590 is exposed. At this time, on the front surface side of the semiconductor substrate 501, a part of the insulating layer 503 is removed, and a part of the side surface of the N⁺ impurity diffusion layer 590 is exposed.

The contact plug 630 is disposed on the insulating layer 503 so as to protrude on the pixels, and is connected to the N⁺ impurity diffusion layer 590. At this time, the tip of the contact plug 630 enters the trench 502 and is brought into contact with the side surface of the N⁺ impurity diffusion layer 590.

As described above, according to the above-described ninth embodiment, the ends in the width direction of the gate electrodes 521 to 524 are disposed on the insulating layer 503 embedded in the trench 502, and therefore the gate electrodes 521 to 524 can be isolated for respective pixels while improving the uniformity of the gate widths of the gate electrodes 521 to 524 among pixels.

### 10. Tenth Embodiment

In the ninth embodiment described above, the ends in the width direction of the gate electrodes 521 to 524 of the transfer transistors are disposed on the pixel isolation region. In a tenth embodiment, the ends in the width direction of gate electrodes 821 to 824 of transfer transistors are embedded in a trench 802, and the channel region of the transfer transistors is enlarged to the side surface side of the trench 802.

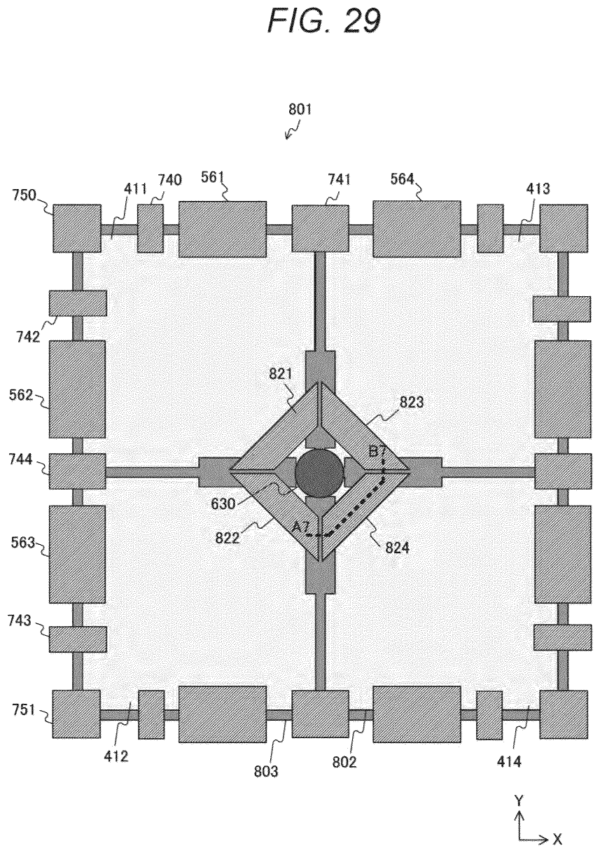

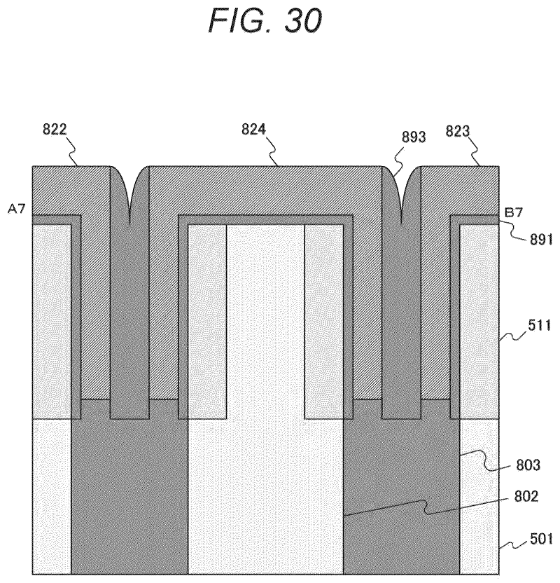

FIG. 29 is a plan view illustrating a configuration example of a cell according to the tenth embodiment. FIG. 30 is a cross-sectional view of a configuration example taken along line A7-B7 of the configuration example of the cell according to the tenth embodiment.

In the configuration of the tenth embodiment in FIGS. 29 and 30, a cell 801 is provided instead of the cell 703 of the above-described ninth embodiment. The cell 801 is provided with the trench 802, an insulating layer 803, and the gate electrodes 821 to 824 instead of the trench 502, the insulating layer 503, and the gate electrodes 521 to 524 of the above-described ninth embodiment. Other configurations of the cell 801 of the tenth embodiment are similar to those of the cell 703 of the ninth embodiment described above.

The trench 802 is disposed in the semiconductor substrate 501 so as to isolate each pixel. The insulating layer 803 is embedded in the trench 802. The ends in the width direction of each of the gate electrodes 821 to 824 are disposed in the trench 802, as illustrated in FIG. 30. Here, the insulating layer 803 is removed in accordance with the depth of the ends in the width direction of each of the gate electrodes 821 to 824 embedded in the trench 802. At this time, the ends in the width direction of each of the gate electrodes 821 to 824 are located on the side surface of the trench 802 with a gate insulating film 891 interposed on the insulating layer 803. In the region where the ends in the width direction of the gate electrodes 821 to 824 are disposed, the width of the trench 802 is larger than the width of the trench 502.

In addition, a sidewall 893 is formed on the side wall of each of the gate electrodes 821 to 824. At this time, the sidewall 893 is disposed within the trench 802 and can ensure the insulation of each of the gate electrodes 821 to 824 embedded in the trench 802.

As described above, according to the above-described tenth embodiment, the ends in the width direction of each of the gate electrodes 821 to 824 are disposed in the trench 802, and therefore the channel region of each of the transfer transistors 421 to 424 can be enlarged to the side surface side of the trench 802. Therefore, it is possible to improve the cutoff characteristics of each of the transfer transistors 421 to 424 and improve the transfer efficiency while suppressing an increase in the area occupied by each of the transfer transistors 421 to 424 on the pixels.

### 11. Eleventh Embodiment

In the above-described tenth embodiment, in the configuration in which the channel region of the transfer transistor is enlarged to the side surface side of the trench 802, the contact plug 630 connected in common with the floating diffusions each isolated by the pixel isolation region is provided. In an eleventh embodiment, in the configuration in which the channel region of the transfer transistor is enlarged to the side surface side of the trench 802, the base layer 730 connected in common with the floating diffusions each isolated by the pixel isolation region is provided.

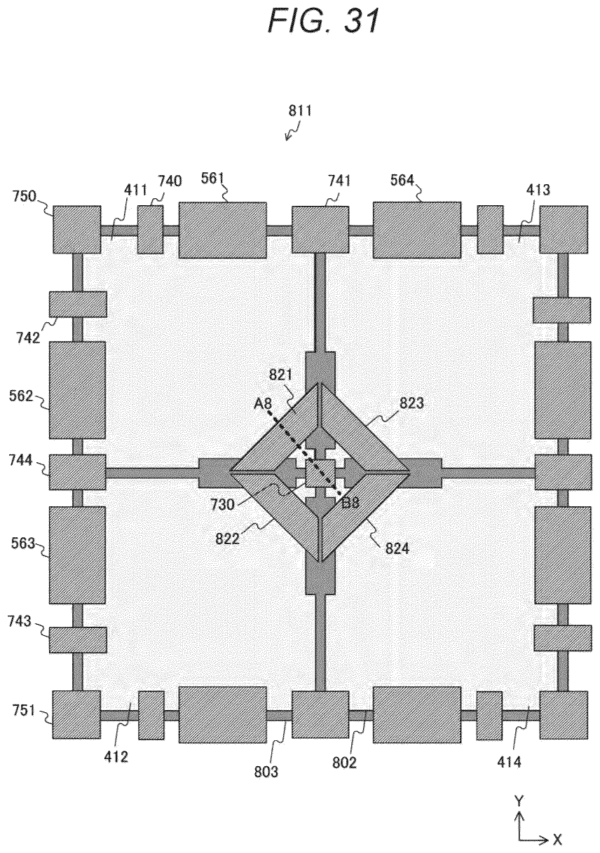

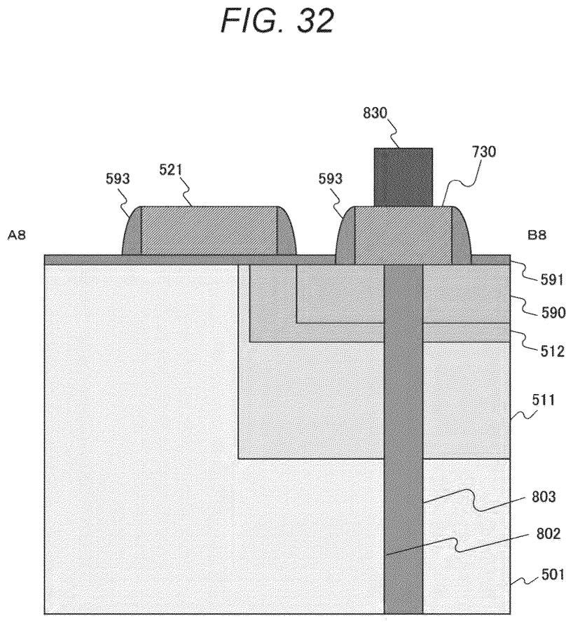

FIG. 31 is a plan view illustrating a configuration example of a cell according to the eleventh embodiment. FIG. 32 is a cross-sectional view of a configuration example taken along line A8-B8 of the configuration example of the cell according to the eleventh embodiment.

In the configuration of the eleventh embodiment in FIGS. 31 and 32, a cell 811 is provided instead of the cell 801 of the above-described tenth embodiment. The cell 811 is provided with the base layer 730 of the above-described seventh embodiment instead of the contact plug 630 of the above-described tenth embodiment. Other configurations of the cell 811 of the eleventh embodiment are similar to those of the cell 801 of the tenth embodiment described above.

The base layer 730 is disposed on the insulating layer 803 so as to protrude on the pixels, and is connected to the N⁺ impurity diffusion layer 590. The sidewall 593 is formed on the side wall of the base layer 730. A contact plug 830 is provided on the base layer 730.

As described above, according to the above-described eleventh embodiment, since the base layer 730 connected to the N⁺ impurity diffusion layer 590 is disposed on the insulating layer 803 so as to protrude on the pixels, it is possible to prevent the contact plug 830 from entering the trench 802. Therefore, the parasitic capacitance between the contact plug 830 and the floating diffusions can be reduced, and a decrease in conversion efficiency can be suppressed.

In the above-described fifth to eleventh embodiments, the 4-pixel-1-cell structure in which four pixels are arranged in a matrix per cell has been taken as an example, but an 8-pixel-1-cell structure in which eight pixels are arranged per cell may be employed.

### 12. Twelfth Embodiment

In the above-described fifth embodiment, the pixel transistors are provided in the trench in the 4-pixel-1-cell structure. In a twelfth embodiment, pixel transistors are provided in a trench in an 8-pixel-1-cell structure in which eight pixels are arranged in two rows and four columns.

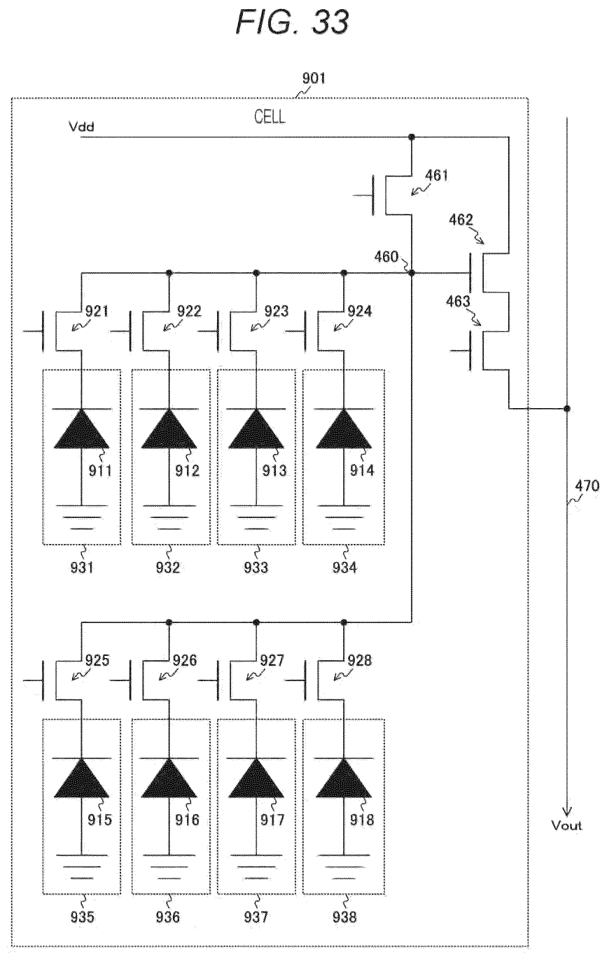

FIG. 33 is a diagram illustrating a circuit configuration example of pixels according to the twelfth embodiment. FIG. 33 illustrates the 8-pixel-1-cell structure in which eight pixels are arranged in two rows and four columns per cell.

In FIG. 33, a cell 901 includes pixels 931 to 938. In addition, the cell 901 includes transfer transistors 921 to 928, the reset transistor 461, the drive transistor 462, the selection transistor 463, and the floating diffusion 460. The pixels 931 to 938 include photodiodes 911 to 918, respectively. Cathodes of the respective photodiodes 911 to 918 are connected to the floating diffusion 460 via the transfer transistors 921 to 928, respectively. Other configurations of the cell 901 of FIG. 33 are similar to those of the cell 500 of FIG. 11. The configuration of any one of the fifth to eleventh embodiments described above may be applied to the cell 901.

As described above, in the above-described twelfth embodiment, the pixel transistors are provided in the trench in the 8-pixel-1-cell structure in which eight pixels are arranged in two rows and four columns. As a result, the pixel transistors can be shared by the eight pixels 931 to 938 while reducing the area occupied by the pixel transistors in the pixel region, and therefore the pixel region can be enlarged as compared with the 4-pixel-1-cell structure.

### 13. Thirteenth Embodiment

In the above-described fifth embodiment, the pixel transistors are provided in the trench in the 4-pixel-1-cell structure. In a thirteenth embodiment, pixel transistors are provided in a trench in an 8-pixel-1-cell structure in which eight pixels are arranged in one row and eight columns.

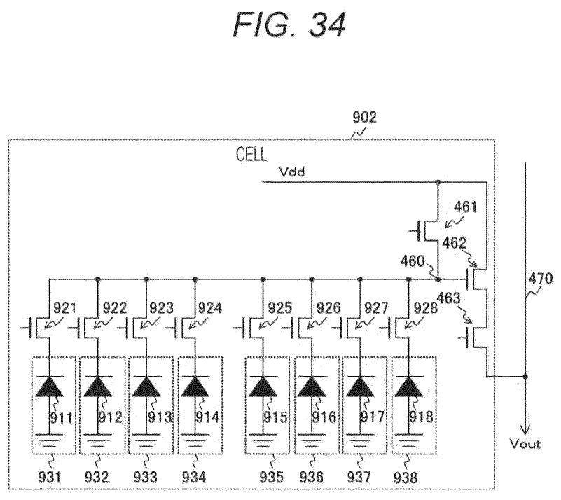

FIG. 34 is a diagram illustrating a circuit configuration example of pixels according to the thirteenth embodiment. FIG. 34 illustrates an 8-pixel-1-cell structure in which eight pixels are arranged in one row and eight columns per cell.

In FIG. 34, a cell 902 includes the pixels 931 to 938 arranged in one row and eight columns. Other configurations of the cell 902 of FIG. 34 are similar to those of the cell 901 of FIG. 33. The configuration of any one of the fifth to eleventh embodiments described above may be applied to the cell 902.

As described above, in the above-described thirteenth embodiment, the pixel transistors are provided in the trench in the 8-pixel-1-cell structure in which eight pixels are arranged in one row and eight columns. As a result, the pixel transistors can be shared by the eight pixels 931 to 938 while reducing the area occupied by the pixel transistors in the pixel region, and therefore the pixel region can be enlarged as compared with the 4-pixel-1-cell structure.

Note that the embodiments described above show examples for embodying the present technology, and the matters in the embodiments and the matters specifying the invention in the claims have corresponding relationships, respectively. Similarly, the matters specifying the invention in the claims and the matters with the same names in the embodiments of the present technology have correspondence relationships, respectively. However, the present technology is not limited to the embodiments, and can be embodied by applying various modifications to the embodiments without departing from the gist of the present technology. In addition, effects described in the present specification are merely examples and are not limited, and other effects may be provided.

Furthermore, the present technology can also have the following configurations.
(1) A solid-state imaging device including:
a trench for isolating a pixel; and
a pixel transistor that forms a channel region along a side surface of the trench in a direction intersecting a depth direction of the trench.
(2) The solid-state imaging device according to (1), in which
at least a part of a gate electrode of the pixel transistor is located in the trench.
(3) The solid-state imaging device according to (1) or (2), in which
the direction intersecting the depth direction of the trench includes at least one of a column direction or a row direction.
(4) The solid-state imaging device according to any one of (1) to (3), in which
the pixel transistor includes at least one of a drive transistor, a selection transistor, a reset transistor, or a transfer transistor.
(5) The solid-state imaging device according to claim 1, in which
at least one of a source, a drain, or a floating diffusion of the pixel transistor is located on the side surface of the trench.
(6) The solid-state imaging device according to any one of (1) to (5), further including:
an insulating layer embedded in a part of the trench in the depth direction, in which
a part of a gate electrode of the pixel transistor is located on the side surface of the trench on the insulating layer with a gate insulating film interposed between the part of the gate electrode and the side surface.
(7) The solid-state imaging device according to any one of (1) to (6), in which
a part of a gate electrode of the pixel transistor is located on the pixel.
(8) The solid-state imaging device according to (7), further including a spacer insulating layer located below the gate electrode on the pixel.
(9) The solid-state imaging device according to any one of (1) to (8), in which
at least one of sources, drains, or floating diffusions of adjacent pixels are isolated from each other by the trench.
(10) The solid-state imaging device according to any one of (1) to (9), further including:
a contact plug connected to each of sources, drains, and floating diffusions of adjacent pixels isolated from each other by the trench; and
a wiring line that connects the sources, the drains, and the floating diffusions each other which are isolated by the trench, via the contact plug connected to each of the sources, the drains, and the floating diffusions isolated by the trench.
(11) The solid-state imaging device according to any one of (1) to (10), further including a contact plug connected across the trench to each of sources, drains, and floating diffusions isolated from each other by the trench between adjacent pixels.
(12) The solid-state imaging device according to any one of (1) to (11), further including a base layer that is connected across the trench to each of sources, drains, and floating diffusions isolated from each other by the trench between adjacent pixels, and includes the same material as a material of a gate electrode of the pixel transistor.
(13) The solid-state imaging device according to (12), in which
a part of the base layer connected to each of the sources and the drains is located in the trench.
(14) The solid-state imaging device according to (12), in which
the materials of the gate electrode and the base layer include polycrystalline silicon into which impurities are introduced.
(15) The solid-state imaging device according to any one of (1) to (14), in which
a transfer transistor used as the pixel transistor has a planar structure, and an end in a width direction of a gate electrode of the transfer transistor is located on an insulating layer embedded in the trench.
(16) The solid-state imaging device according to any one of (1) to (15), in which
an end in a width direction of a gate electrode of a transfer transistor used as the pixel transistor is located on the side surface of the trench.

### REFERENCE SIGNS LIST

201 Pixel
211 Photodiode
301 Semiconductor substrate
302 Trench
303, 308 Insulating layer
304 Gate electrode
305 to 307 Wiring line
309 Color filter
310 Microlens

1. A solid-state imaging device comprising:
a trench that isolates a pixel; and
a pixel transistor that forms a channel region along a side surface of the trench in a direction intersecting a depth direction of the trench.

2. The solid-state imaging device according to claim 1, wherein
at least a part of a gate electrode of the pixel transistor is located in the trench.

3. The solid-state imaging device according to claim 1, wherein
the direction intersecting the depth direction of the trench includes at least one of a column direction or a row direction.

4. The solid-state imaging device according to claim 1, wherein
the pixel transistor includes at least one of a drive transistor, a selection transistor, a reset transistor, or a transfer transistor.

5. The solid-state imaging device according to claim 1, wherein
at least one of a source, a drain, or a floating diffusion of the pixel transistor is located on the side surface of the trench.

6. The solid-state imaging device according to claim 1, further comprising:
an insulating layer embedded in a part of the trench in the depth direction, wherein
a part of a gate electrode of the pixel transistor is located on the side surface of the trench on the insulating layer with a gate insulating film interposed between the part of the gate electrode and the side surface.

7. The solid-state imaging device according to claim 1, wherein
a part of a gate electrode of the pixel transistor is located on the pixel.

8. The solid-state imaging device according to claim 7, further comprising a spacer insulating layer located below the gate electrode of the pixel transistor on the pixel.

9. The solid-state imaging device according to claim 1, wherein
at least one of sources, drains, or floating diffusions of adjacent pixels are isolated from each other by the trench.

10. The solid-state imaging device according to claim 1, further comprising:
a contact plug connected to each of sources, drains, and floating diffusions of adjacent pixels isolated from each other by the trench; and
a wiring line that connects the sources, the drains, and the floating diffusions each other which are isolated by the trench, via the contact plug connected to each of the sources, the drains, and the floating diffusions isolated by the trench.

11. The solid-state imaging device according to claim 1, further comprising a contact plug connected across the trench to each of sources, drains, and floating diffusions isolated from each other by the trench between adjacent pixels.

12. The solid-state imaging device according to claim 1, further comprising a base layer that is connected across the trench to each of sources, drains, and floating diffusions isolated from each other by the trench between adjacent pixels, and includes the same material as a material of a gate electrode of the pixel transistor.

13. The solid-state imaging device according to claim 12, wherein
a part of the base layer connected to each of the sources and the drains is located in the trench.

14. The solid-state imaging device according to claim 12, wherein
the materials of the gate electrode of the pixel transistor and the base layer include polycrystalline silicon into which impurities are introduced.

15. The solid-state imaging device according to claim 1, wherein
a transfer transistor used as the pixel transistor has a planar structure, and an end in a width direction of a gate electrode of the transfer transistor is located on an insulating layer embedded in the trench.

16. The solid-state imaging device according to claim 1, wherein
an end in a width direction of a gate electrode of a transfer transistor used as the pixel transistor is located on the side surface of the trench.
